(19) United States
(12) Patent Application Publication
(10) Pub. No.: US 2025/0372562 A1
(43) Pub. Date: Dec. 4, 2025

(54) FAN-OUT WAFER-LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/224,919

(22) Filed: Jun. 2, 2025

(30) Foreign Application Priority Data
Jun. 4, 2024 (TW) 113120648

(51) Int. Cl. H01L 23/00

(52) U.S. Cl. CPC H01L 24/24; H01L 2224/24011; H01L 2224/24226

(57) ABSTRACT

A fan-out wafer level packaging (FOWLP) unit including a substrate, at least one lower-layered die, a first dielectric layer, a plurality of first conductive circuits, a second dielectric layer, a plurality of second conductive circuits, at least one upper-layered die, a third dielectric layer, a plurality of third conductive circuits, a fourth dielectric layer, a plurality of fourth conductive circuits, and an outer protective layer is provided. The upper-layered die and the lower-layered die are stacked vertically with an interval between them and corresponding to each other. Each of the fourth conductive circuits forms a solder pad in respective opening of the outer protective layer. The upper-layered die and the lower-layered die are both electrically connected to the outside through solder pads around a chip area defined on a second surface of the upper-layered die.

### CROSS-REFERENCE TO RELATED APPLICATIONS

This non-provisional application claims priority under 35 U.S.C. § 119(a) on Patent Application No(s). 113120648 filed in Taiwan, R.O.C. on Jun. 4, 2024, the entire contents of which are hereby incorporated by reference.

### BACKGROUND OF THE INVENTION

The present invention relates to a packaging unit, especially to a fan-out wafer level packaging (FOWLP) unit.

Packaging technology with features of compact design, high efficiency and reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree. The most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, in order to provide products with higher performance or more functions, at least two dies are disposed in FOWLP unit and the multi-die type FOWLP unit is integrated by RDL. At the moment, space requirement for designing the conductive circuits in the RDL of the FOWLP unit is increased and manufacturing of the conductive circuits in the RDL is more crucial.

### SUMMARY OF THE INVENTION

Therefore, it is a primary object of the present invention to provide a fan-out wafer level packaging (FOWLP) unit which includes a substrate, at least one lower-layered die, a first dielectric layer, at least one first conductive circuit, a second dielectric layer, at least one second conductive circuit, at least one upper-layered die, a third dielectric layer, at least one third conductive circuit, a fourth dielectric layer, at least one fourth conductive circuit, and an outer protective layer. The lower-layered die and the upper-layered die are located at an upper position and a lower position, corresponding to, and stacked over each other with intervals between them.

The fourth conductive circuit forms a solder pad in an opening of the outer protective layer. The lower-layered die and the upper-layered die are both electrically connected to the outside through the solder pads around a chip area above a second surface of the upper-layered die.

In order to achieve the above object, a fan-out wafer level packaging (FOWLP) unit according to the present invention includes a substrate, at least one lower-layered die, a first dielectric layer, at least one first conductive circuit, a second dielectric layer, at least one second conductive circuit, at least one upper-layered die, a third dielectric layer, at least one third conductive circuit, a fourth dielectric layer, at least one fourth conductive circuit, and an outer protective layer. The substrate is provided with a first surface. The lower-layered die is cut from at least one wafer and composed of a first surface, a second surface opposite to the first surface, and a plurality of die pads disposed on the second surface. The first dielectric layer is covering the lower-layered die correspondingly and provided with a plurality of first slots extending in a horizontal direction. The die pads of the lower-layered die are electrically connected to the outside through the first slots. The first conductive circuit is formed by a metal paste filled in the respective first slots and electrically connected to the die pads of the lower-layered die. The second dielectric layer is covering the lower-layered die correspondingly and located over first dielectric layer. The second dielectric layer is provided with a plurality of second slots extending in a horizontal direction and communicating with the first slots. The second conductive circuit is formed by a metal paste filled in the respective second slots and electrically connected to the first conductive circuit. The upper-layered die is cut from at least one wafer and having a first surface and a second surface which is opposite to the first surface and provided with a plurality of die pads. An area just above the second surface is defined as a chip area. The third dielectric layer is covering the upper-layered die correspondingly. A plurality of third slots extending horizontally is formed on the third dielectric layer and the die pads of the upper-layered die are electrically connected to the outside through the third slots. The third conductive circuit is formed by a metal paste filled into the respective third slots and electrically connected to the second conductive circuit. The fourth dielectric layer is covering the upper-layered die correspondingly and located over the third dielectric layer. A plurality of fourth slots extending horizontally is formed on the fourth dielectric layer and communicating with the third slots correspondingly. The fourth conductive circuit is formed by a metal paste filled into the respective fourth slots and electrically connected to the third conductive circuit or the die pads of the upper-layered die. The outer protective layer is disposed over the fourth dielectric layer and provided with a plurality of openings. At least one of the openings is located around a chip area above the second surface of the lower-layered die, and the chip area above the second surface of the upper-layered die. The fourth conductive circuit is exposed through the opening to form a solder pad in the opening. The lower-layered die and the upper-layered die respectively are disposed on an upper position and a lower position, corresponding to each other, and stacked on the substrate with an interval between them. The lower-layered die is electrically connected to the upper-layered die through the first conductive circuit, the second conductive circuit, the third conductive circuit, and the fourth conductive circuit in turn. The lower-layered die is also electrically connected to the outside through the first conductive circuit, the second conductive circuit, the third conductive circuit, the fourth conductive circuit, and the solder pads around the chip area above the second surface of the upper-layered die in turn. Thereby the fan-out wafer level packaging (FOWLP) unit is formed.

A method of manufacturing the fan-out wafer level packaging (FOWLP) unit includes the following steps. Step S1: providing a substrate. Step S2: arranging a plurality of lower-layered dies cut from at least one wafer at the substrate and allowing a first surface of the respective lower-layered dies to be fixed on the substrate. Each of the lower-layered die is provided with a second surface opposite to the first surface and a plurality of die pads is disposed on the second surface. Step S3: covering the at least one lower-layered die with a first dielectric layer and forming a plurality of first slots extending horizontally on the first dielectric layer so that the respective die pads of the lower-layered die are exposed through the respective first slots. Then filling a metal paste into the first slots and a level of the metal paste is higher than a surface of the first dielectric layer. And grinding the metal paste with the level higher than the surface of the first dielectric layer to make the surface of the metal paste flush with the surface of the first dielectric layer and form a plurality of first conductive circuits. Later covering the first dielectric layer with a second dielectric layer and forming a plurality of second slots extending horizontally on the second dielectric layer so that the respective first conductive circuits are exposed through the respective second slots. Next filling a metal paste into the respective second slots and a level of the metal paste is higher than a surface of the second dielectric layer. And grinding the metal paste with the level higher than the surface of the second dielectric layer to make the surface of the metal paste flush with the surface of the second dielectric layer and form a plurality of second conductive circuits. Step S4: disposing a plurality of upper-layered dies cut from at least one wafer on the second dielectric layer. Each of the upper-layered dies is provided with a first surface and a second surface opposite to the first surface. A plurality of die pads is disposed on the second surface and an area just above the second surface is defined as a chip area. Step S5: covering the respective upper-layered dies with a third dielectric layer and forming a plurality of third slots extending horizontally on the third dielectric layer so that the respective die pads of the respective upper-layered dies are exposed through the respective third slots of the third dielectric layer. Then filling a metal paste into the respective third slots and a level of the metal paste is higher than a surface of the third dielectric layer. And grinding the metal paste with the level higher than the surface of the third dielectric layer to make the surface of the metal paste flush with the surface of the third dielectric layer and form a plurality of third conductive circuits. Next covering the third dielectric layer with a fourth dielectric layer and forming a plurality of fourth slots extending horizontally on the fourth dielectric layer so that the respective third conductive circuits in the respective fourth slots are exposed through the respective fourth slots. Then filling a metal paste into the respective fourth slots and a level of the metal paste is higher than a surface of the fourth dielectric layer. And grinding the metal paste with the level higher than the surface of the fourth dielectric layer to make the surface of the metal paste flush with the surface of the fourth dielectric layer and form a plurality of fourth conductive circuits. Step S6: covering the fourth dielectric layer with an outer protective layer. Step S7: forming a plurality of openings on the outer protective layer and allowing at least one of the openings to be located around the chip area above the second surface of the respective upper-layered dies so that each of the respective fourth conductive circuits is exposed through the corresponding opening to form a solder pad in the opening. Step S8: performing cutting to form a plurality of the fan-out wafer-level packaging (FOWLP) units.

Preferably, an area just above the second surface of the lower-layered dies is defined as a chip area. The lower-layered dies are electrically connected to the outside through the first conductive circuit, the second conductive circuit, the third conductive circuit, the fourth conductive circuit, and the solder pads around the chip area above the second surface of the lower-layered die in turn.

Preferably, the at least one lower-layered die and the at least one upper-layered die are cut from the same wafer or different wafers.

Preferably, the substrate includes silicon substrate, glass substrate, and ceramic substrate.

Preferably, the metal paste which forms the first, the second, the third, and the fourth conductive circuits includes silver paste, nano-silver paste, copper paste, and nano-copper paste.

Preferably, the first surface of the lower-layered die is disposed on the substrate by a die attach film (DAF). The first surface of the upper-layered die is arranged at the second dielectric layer by a die attach film (DAF).

Preferably, each of the openings is provided with a solder ball which is electrically connected to the solder pad in the opening correspondingly. The FOWLP unit is electrically connected to and disposed on an electronic component by the solder balls.

Preferably, each of the openings is provided with a projection which is electrically connected to the solder pad in the opening correspondingly. The FOWLP unit forms welding points on the projection and an electronic component by wire bonding and the projection and the electronic component are electrically connected by a bonding wire.

### BRIEF DESCRIPTION OF THE DRAWINGS

FIG. 1 is a side sectional view showing a fan-out wafer level packaging unit disposed on an electronic component of an embodiment according to the present invention;

FIG. 2 is a side sectional view showing a fan-out wafer level packaging unit electrically connected to an electronic component by wire bonding of an embodiment according to the present invention;

FIG. 3 is a side sectional view showing a lower-layered die disposed on a substrate of an embodiment according to the present invention;

FIG. 4 is a side sectional view showing a lower-layered die covered with a first dielectric layer of the embodiment in FIG. 3 according to the present invention;

FIG. 5 is a side sectional view showing a metal paste filled in first slots of the embodiment in FIG. 4 according to the present invention;

FIG. 6 is a side sectional view showing grinding of a metal paste with a level higher than a surface of the first dielectric layer of the embodiment in FIG. 5 according to the present invention;

FIG. 7 is a side sectional view showing a second dielectric layer arranged over the first dielectric layer of the embodiment in FIG. 6 according to the present invention;

FIG. 8 is a side sectional view showing a metal paste filled in second slots of the embodiment in FIG. 7 according to the present invention;

FIG. 9 is a side sectional view showing grinding of a metal paste with a level higher than a surface of the second dielectric layer of the embodiment in FIG. 8 according to the present invention;

FIG. 10 is a side sectional view showing an upper-layered die arranged over the second dielectric layer of the embodiment in FIG. 9 according to the present invention;

FIG. 11 is a side sectional view showing the upper-layered die covered with a third dielectric layer of the embodiment in FIG. 10 according to the present invention;

FIG. 12 is a side sectional view showing a metal paste filled in third slots of the embodiment in FIG. 11 according to the present invention;

FIG. 13 is a side sectional view showing grinding of a metal paste with a level higher than a surface of the third dielectric layer of the embodiment in FIG. 12 according to the present invention;

FIG. 14 is a side sectional view showing a fourth dielectric layer arranged over the third dielectric layer of the embodiment in FIG. 13 according to the present invention;

FIG. 15 is a side sectional view showing a metal paste filled in fourth slots of the embodiment in FIG. 14 according to the present invention;

FIG. 16 is a side sectional view showing grinding of a metal paste with a level higher than a surface of the fourth dielectric layer of the embodiment in FIG. 15 according to the present invention;

FIG. 17 is a side sectional view showing an outer protective layer disposed on the fourth dielectric layer of the embodiment in FIG. 16 according to the present invention;

FIG. 18 is a side sectional view showing a solder ball disposed on an opening of the embodiment in FIG. 17 according to the present invention;

FIG. 19 is a side sectional view showing a projection disposed on an opening of the embodiment in FIG. 17 according to the present invention.

### DETAILED DESCRIPTION OF THE PREFERRED EMBODIMENT

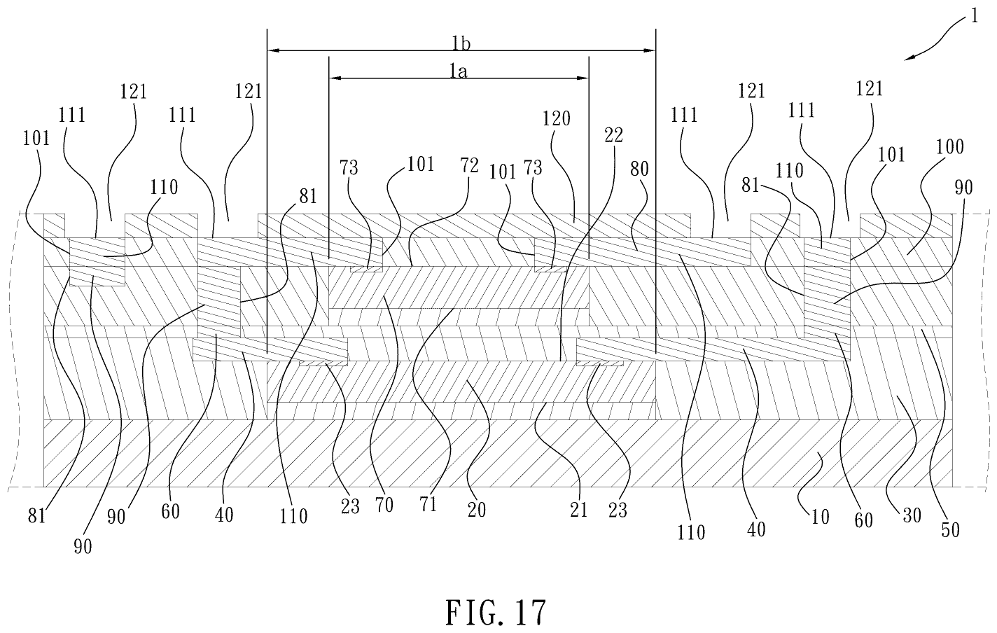

Refer to FIG. 17, a fan-out wafer level packaging (FOWLP) unit 1 includes a substrate 10, at least one lower-layered die 20, a first dielectric layer 30, at least one first conductive circuit 40, a second dielectric layer 50, at least one second conductive circuit 60, at least one upper-layered die 70, a third dielectric layer 80, at least one third conductive circuit 90, a fourth dielectric layer 100, at least one fourth conductive circuit 110, and an outer protective layer 120.

The lower-layered die 20 and the upper-layered die 70 are located at an upper position and a lower position, corresponding to each other, and stacked over the substrate 10 with intervals between them, as shown in FIG. 17. Moreover, there can be a plurality of the lower-layered dies 20 arranged in parallel and spaced apart from one another horizontally and so is a plurality of the upper-layered dies 70 (not shown in figures).

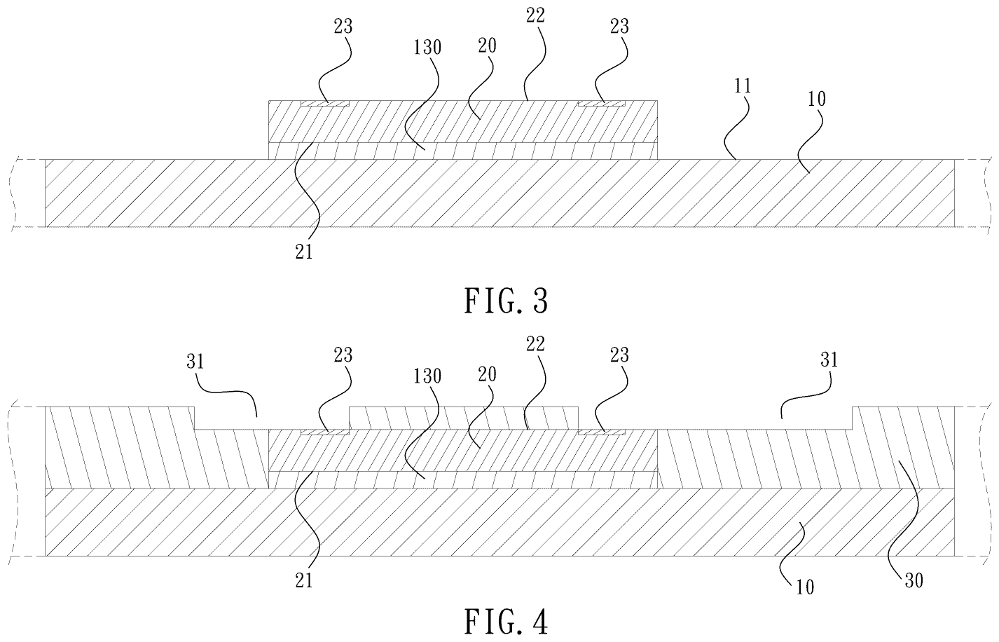

Refer to FIG. 3, the substrate 10 is provided with a first surface 11. The lower-layered die 20 is cut from at least one wafer and provided with a first surface 21, a second surface 22 opposite to the first surface 21, and a plurality of die pads 23 disposed on the second surface 22. The first surface 21 of the lower-layered die 20 is fixed on the first surface 11 of the substrate 10. In FIG. 3, there are two die pads 23 in the lower-layered die and taken as an example, not intended to limit the present invention.

Refer to FIG. 4, the first dielectric layer 30 is covering the lower-layered die 20 correspondingly and provided with a plurality of first slots 31 extending in a horizontal direction. The die pads 23 of the lower-layered die 20 are exposed through the first slots 31.

Refer to FIG. 6, the first conductive circuit 40 is formed by a metal paste 40a filled in the respective first slots 31. The metal paste 40a includes silver paste, nano-silver paste, copper paste, and nano-copper paste, but not limited. The first conductive circuit 40 is electrically connected to the die pads 23 of the lower-layered die 20.

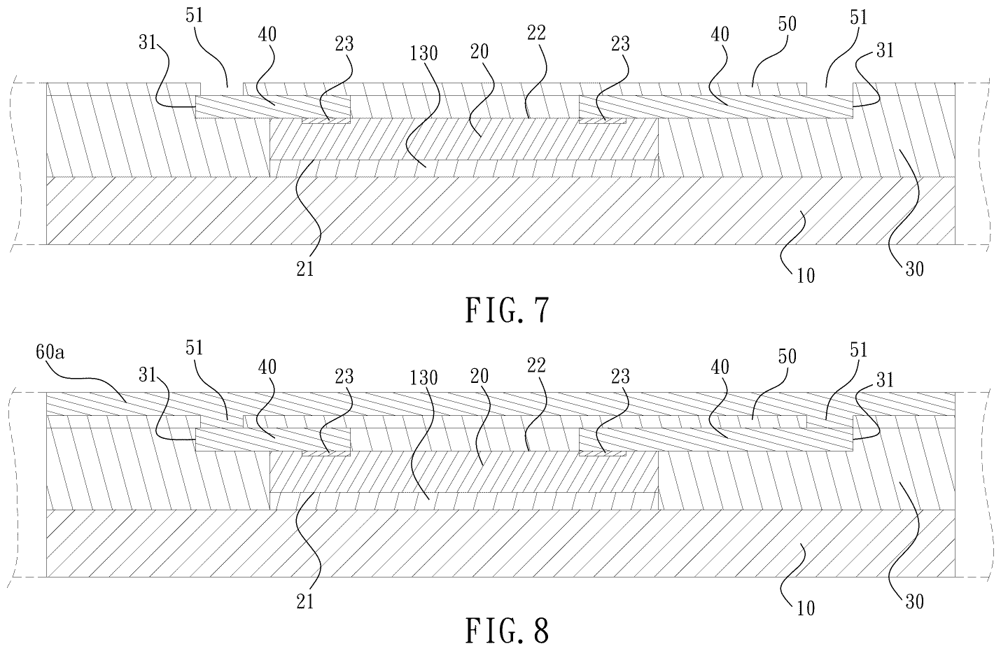

Refer to FIG. 7, the second dielectric layer 50 is covering the lower-layered die 20 correspondingly and located over first dielectric layer 30. The second dielectric layer 50 is provided with a plurality of second slots 51 extending in a horizontal direction and communicating with the first slots 31.

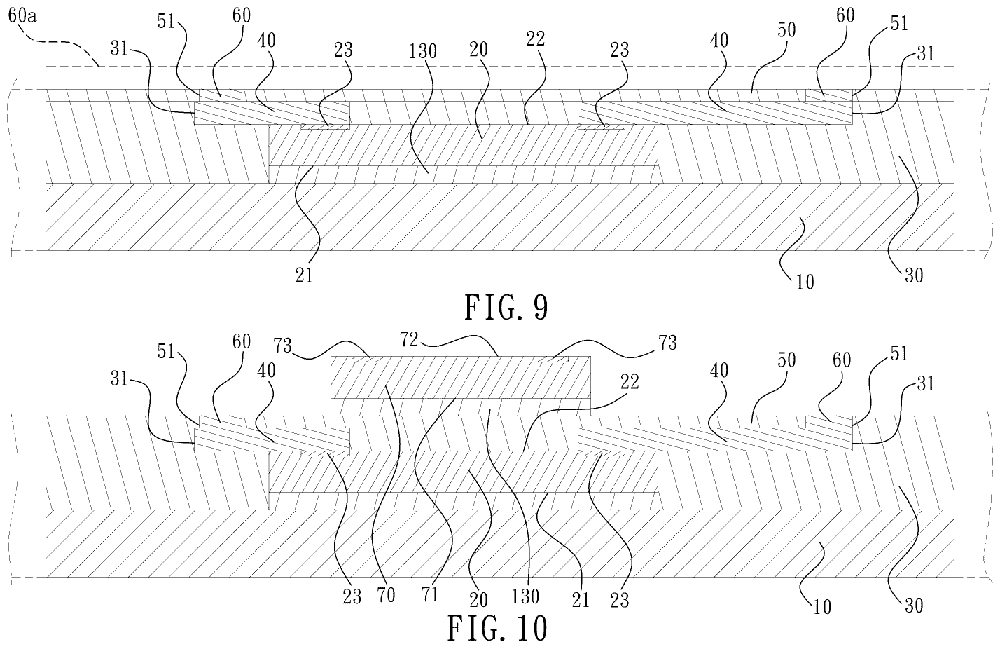

Refer to FIG. 9, the second conductive circuit 60 is formed by a metal paste 60a filled in the respective second slots 51. The metal paste 60a includes silver paste, nano-silver paste, copper paste, and nano-copper paste, but not limited. The second conductive circuit 60 is electrically connected to the first conductive circuit 40.

The upper-layered die 70 is cut from at least one wafer and having a first surface 71 and a second surface 72 opposite to the first surface 71. The first surface 71 is fixed on the second dielectric layer 50 and the second surface 72 is provided with a plurality of die pads 73. An area just above the second surface 72 is defined as a chip area 1a, as shown in FIG. 11. In FIG. 11, the upper-layered die 70 is provided with the two die pads 73 and this is only an example, not intended to limit the present invention.

Refer to FIG. 11, the third dielectric layer 80 is covering the upper-layered die 70 correspondingly. A plurality of third slots 81 extending horizontally is formed on the third dielectric layer 80 and the die pads 73 of the upper-layered die 70 are exposed through the third slots 81.

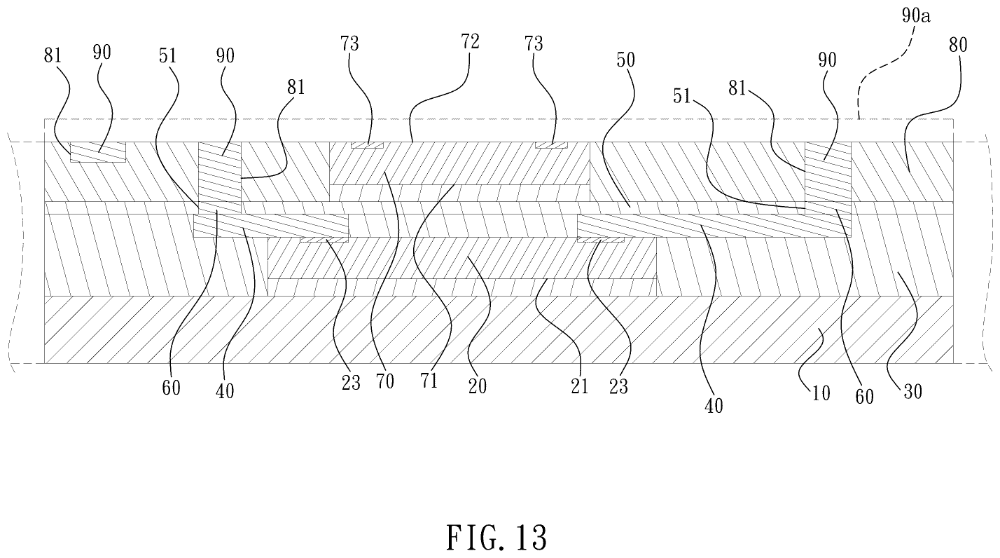

Refer to FIG. 13, the third conductive circuit 90 is formed by a metal paste 90a filled into the respective third slots 81 and electrically connected to the second conductive circuit 60. The metal paste 90a includes, but not limited, silver paste, nano-silver paste, copper paste, and nano-copper paste.

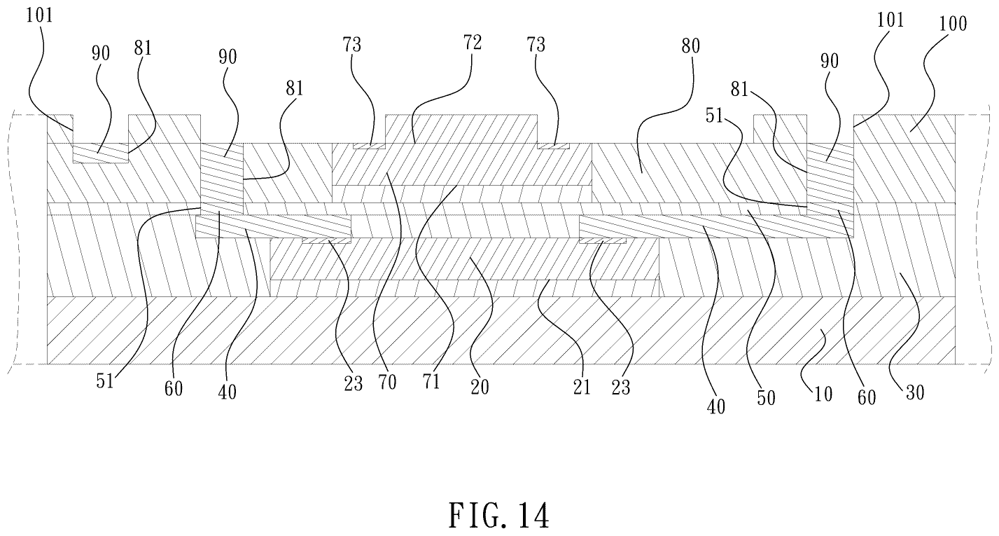

Refer to FIG. 14, the fourth dielectric layer 100 is covering the upper-layered die 70 correspondingly and located over the third dielectric layer 80. A plurality of fourth slots 101 extending horizontally is formed on the fourth dielectric layer 100 and the fourth slots 101 are communicating with the third slots 81 correspondingly.

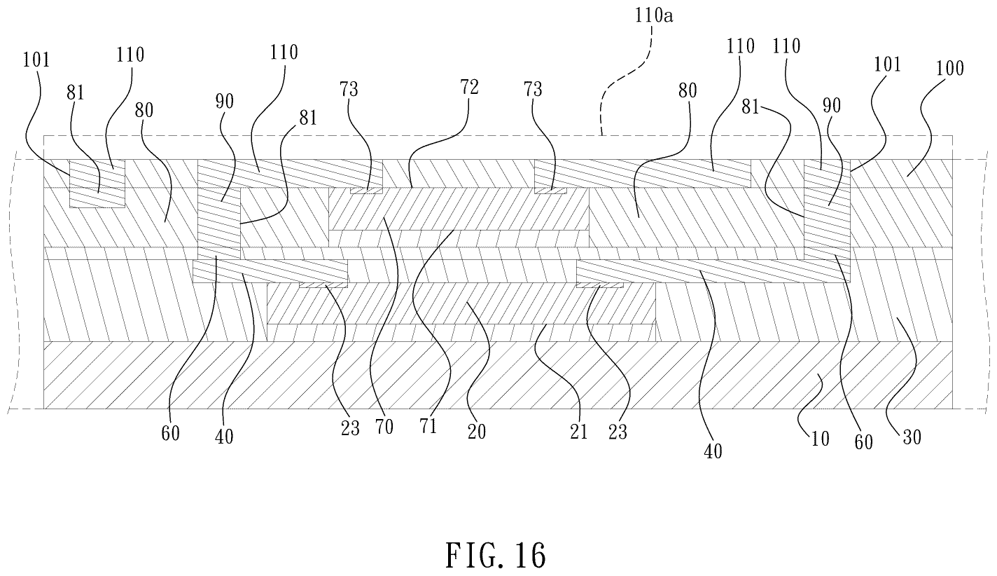

Refer to FIG. 16, the fourth conductive circuit 110 is formed by a metal paste 110a filled into the respective fourth slots 101 and the metal paste 110a includes, but not limited, silver paste, nano-silver paste, copper paste, and nano-copper paste. The fourth conductive circuit 110 is electrically connected to the third conductive circuit 90 or the die pads 73 of the upper-layered die 70.

Refer to FIG. 17, the outer protective layer 120 is disposed over the fourth dielectric layer 100 and provided with a plurality of openings 121. At least one of the openings 121 is located around a chip area 1b above the second surface 22 of the lower-layered die 20, and the chip area 1a above the second surface 72 of the upper-layered die 70. The fourth conductive circuit 110 is exposed through the opening 121 to form a solder pad 111 in the opening 121.

Refer to FIG. 17, the lower-layered die 20 is electrically connected to the upper-layered die 70 through the first conductive circuit 40, the second conductive circuit 60, the third conductive circuit 90, and the fourth conductive circuit 110 in turn. The lower-layered die 20 is also electrically connected to the outside through the first conductive circuit 40, the second conductive circuit 60, the third conductive circuit 90, the fourth conductive circuit 110, and the solder pads 111 around the chip area 1a on the second surface 72 of the upper-layered die 70 in turn. The upper-layered die 70 is electrically connected to the outside through the fourth conductive circuit 110 and the solder pads 111 around the chip area 1a above the second surface 72 of the upper-layered die 70. Thereby the fan-out wafer level packaging (FOWLP) unit 1 is formed.

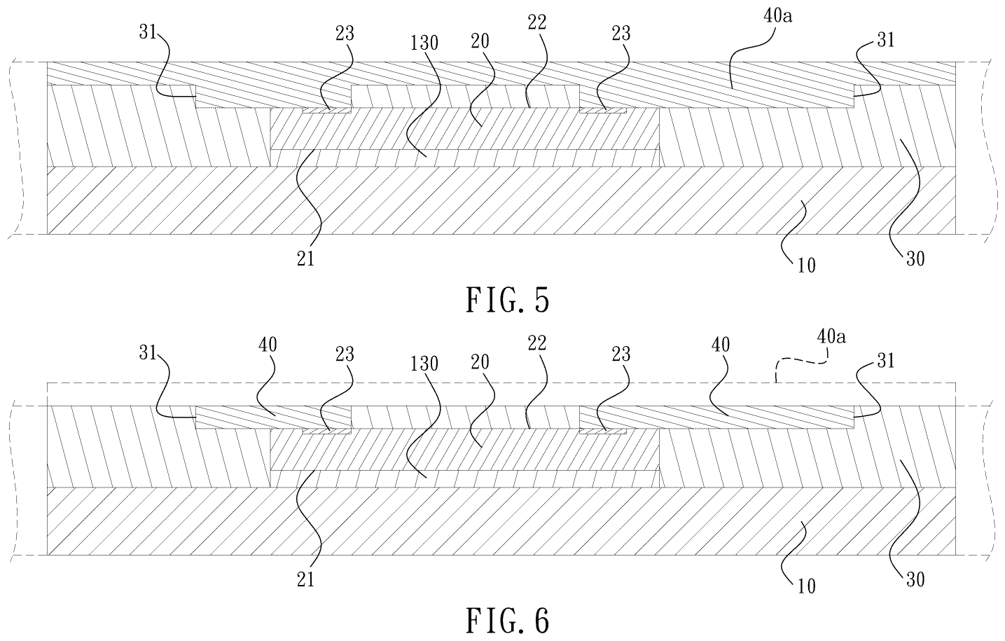

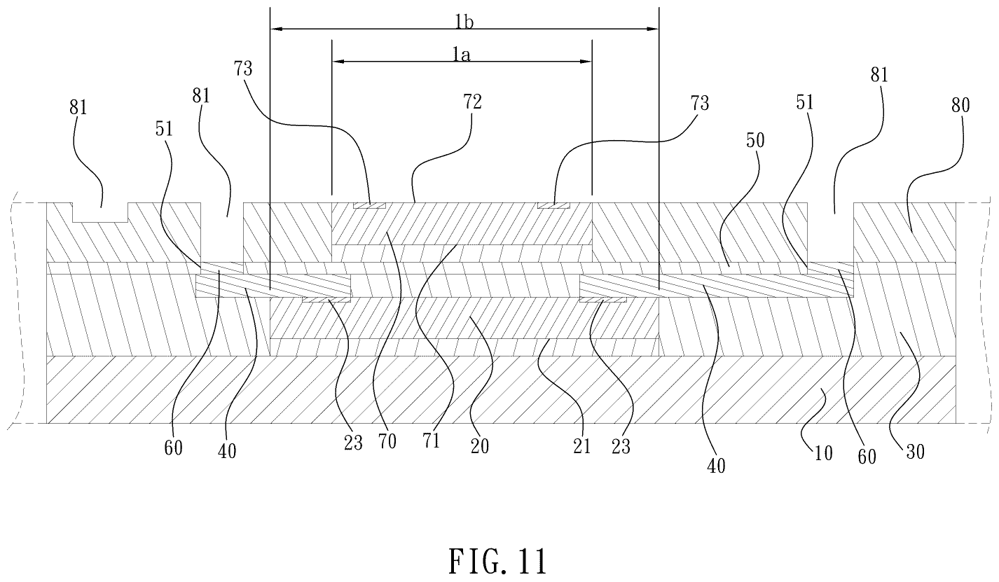

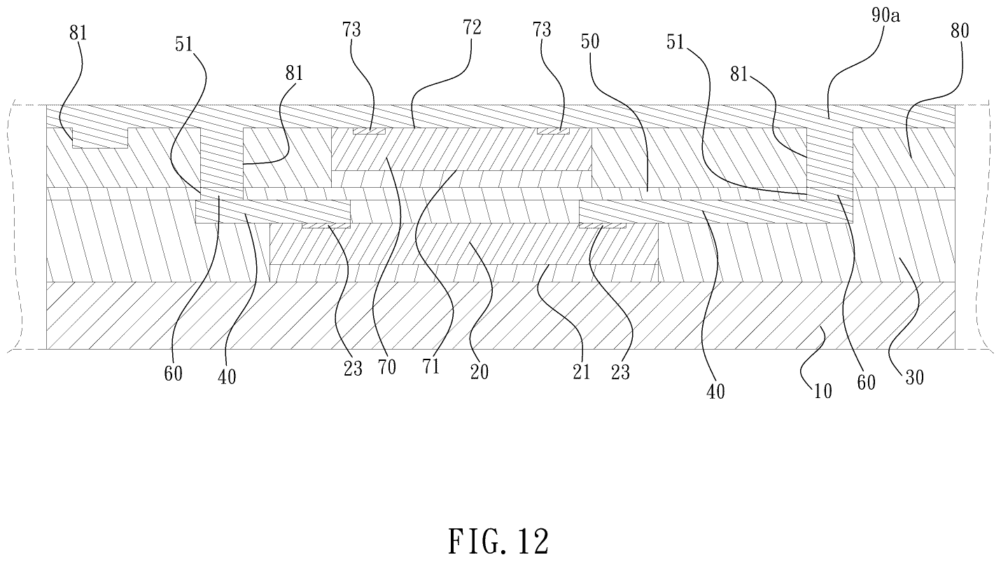

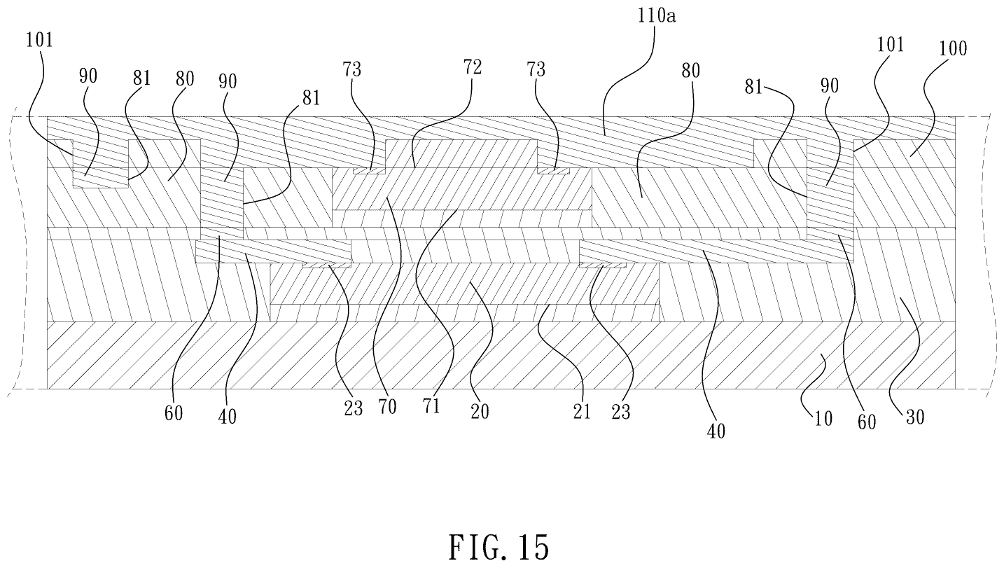

A method of manufacturing the fan-out wafer level packaging (FOWLP) unit 1 includes the following steps.
Step S1: providing a substrate 10, as shown in FIG. 3.
Step S2: arranging a plurality of lower-layered dies 20 cut from at least one wafer at the substrate 10 and allowing a first surface 21 of the respective lower-layered dies 20 to be fixed on the substrate 10, as shown in FIG. 3. Each of the lower-layered die 20 is provided with a second surface 22 opposite to the first surface 21 and a plurality of die pads 23 is disposed on the second surface 22.
Step S3: covering the lower-layered die 20 with a first dielectric layer 30, as shown in FIG. 4, and forming a plurality of first slots 31 horizontally on the first dielectric layer 30 so that the respective die pads 23 of the lower-layered die 20 are exposed through the respective first slots 31. Then filling a metal paste 40a into the first slots 31 and a level of the metal paste 40a is higher than a surface of the first dielectric layer 30, as shown in FIG. 5. And grinding the metal paste 40a with the level higher than the surface of the first dielectric layer 30 to make the surface of the metal paste 40a flush with the surface of the first dielectric layer 30 and form a plurality of first conductive circuits 40, as shown in FIG. 6. Later covering the first dielectric layer 30 with a second dielectric layer 50 and forming a plurality of second slots 51 horizontally on the second dielectric layer 50 so that the respective first conductive circuits 40 in the respective first slots 31 of the first dielectric layer 30 can be exposed through the respective second slots 51 of the second dielectric layer 50, as shown in FIG. 7. Lastly filling a metal paste 60a into the respective second slots 51 of the second dielectric layer 50 and a level of the metal paste 60a is higher than a surface of the second dielectric layer 50, as shown in FIG. 8. And grinding the metal paste 60a with the level higher than the surface of the second dielectric layer 50 to make the surface of the metal paste 60a flush with the surface of the second dielectric layer 50 and form a plurality of second conductive circuits 60, as shown in FIG. 9.
Step S4: disposing a plurality of upper-layered dies 70 cut from at least one wafer on the second dielectric layer 50 which is over the lower-layered die 20, as shown in FIG. 10. Each of the upper-layered dies 70 is provided with a first surface 71 and a second surface 72 opposite to the first surface 71. A plurality of die pads 73 is disposed on the second surface 72 of the respective upper-layered dies 70 and an area just above the second surface 72 of the respective upper-layered dies 70 is defined as a chip area 1a, as shown in FIG. 11.
Step S5: covering the respective upper-layered dies 70 with a third dielectric layer 80 and forming a plurality of third slots 81 horizontally on the third dielectric layer 80 so that the respective die pads 73 of the respective upper-layered dies 70 can be exposed through the respective third slots 81, as shown in FIG. 11. Then filling a metal paste 90a into the respective third slots 81 and a level of the metal paste 90a is higher than a surface of the third dielectric layer 80, as shown in FIG. 12. And grinding the metal paste 90a with the level higher than the surface of the third dielectric layer 80 to make the surface of the metal paste 90a flush with the surface of the third dielectric layer 80 and form a plurality of third conductive circuits 90, as shown in FIG. 13. Next covering the third dielectric layer 80 with a fourth dielectric layer 100 and forming a plurality of fourth slots 101 extending horizontally on the fourth dielectric layer 100 so that the respective third conductive circuits 90 in the respective fourth slots 101 can be exposed through the respective fourth slots 101 of the fourth dielectric layer 100, as shown in FIG. 14. At last filling a metal paste 110a into the respective fourth slots 101 and a level of the metal paste 110a is higher than a surface of the fourth dielectric layer 100, as shown in FIG. 15. And grinding the metal paste 110a with the level higher than the surface of the fourth dielectric layer 100 to make the surface of the metal paste 110a flush with the surface of the fourth dielectric layer 100 and form a plurality of fourth conductive circuits 110, as shown in FIG. 16.
Step S6: covering the fourth dielectric layer 100 with an outer protective layer 120, as shown in FIG. 17.
Step S7: forming a plurality of openings 121 on the outer protective layer 120 and allowing at least one of the openings 121 to be formed around the chip area 1a on the second surface 72 of the respective upper-layered dies 70 so that each of the respective fourth conductive circuits 110 is exposed through the corresponding opening 121 to form a solder pad 111 in the opening 121, as shown in FIG. 17.
Step S8: performing cutting to form a plurality of fan-out wafer-level packaging (FOWLP) units 1, as shown in FIG. 17.

The above steps S3 and S5 are considered as key steps of manufacturing the redistribution layer (RDL) of the FOWLP unit 1. The steps S3 and S5 are easy to be implemented precisely so that the manufacturing process is simplified and the first, the second, the third and the fourth conductive circuits 40, 60, 90, 110 in the RDL have electrical extension in the XY plane and interconnections. At the same time, the FOWLP unit 1 manufactured still has slim size and light weight to a certain degree even the FOWLP unit 1 includes the lower-layered dies 20 and the upper-layered dies 70 respectively located at lower positions and upper positions and stacked on the substrate 10 with intervals therebetween.

Refer to FIG. 17, an area just above the second surface 22 of the lower-layered dies 20 is defined as a chip area 1b. The at least one lower-layered dies 20 can be electrically connected to the outside through the first conductive circuit 40, the second conductive circuit 60, the third conductive circuit 90, the fourth conductive circuit 110, and the solder pads 111 around the chip area 1b on the second surface 22 of the lower-layered die 20 in turn.

Refer to FIG. 17, the lower-layered dies 20 and the upper-layered dies 70 can be cut from the same wafer or different wafers and this helps diversified development and application of the product.

Refer to FIG. 3, the substrate 10 includes silicon substrate, glass substrate, and ceramic substrate, but not limited for diversified development and application of the product.

Refer to FIG. 3, the first surface 21 of the lower-layered die 20 is disposed on the substrate 10 by a die attach film (DAF) 130. Refer to FIG. 10, the first surface 71 of the upper-layered die 70 is arranged at the second dielectric layer 50 by a die attach film (DAF) 130.

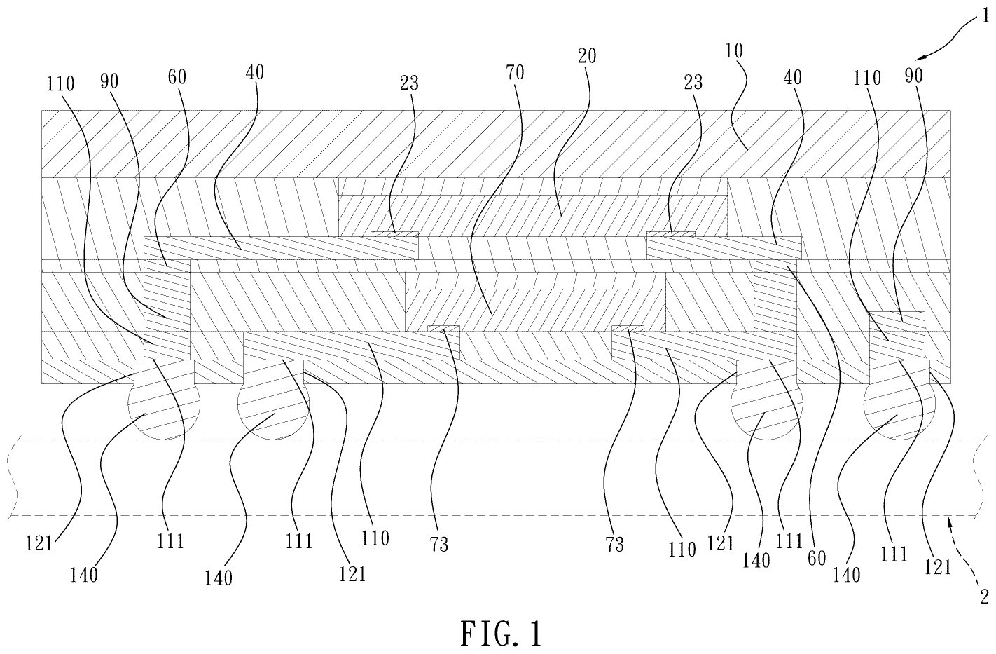

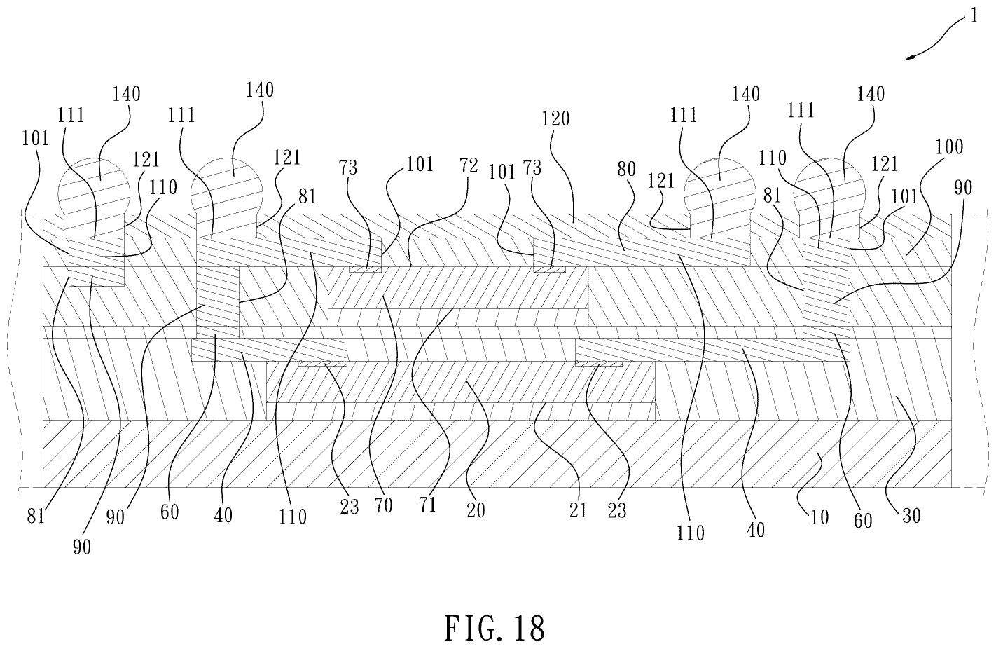

Refer to FIG. 18, each of the openings 121 is provided with a solder ball 140 which is electrically connected to the solder pad 111 in the opening 121 correspondingly. The FOWLP unit 1 is electrically connected to and disposed on an electronic component 2 by the solder balls 140, as shown in FIG. 1.

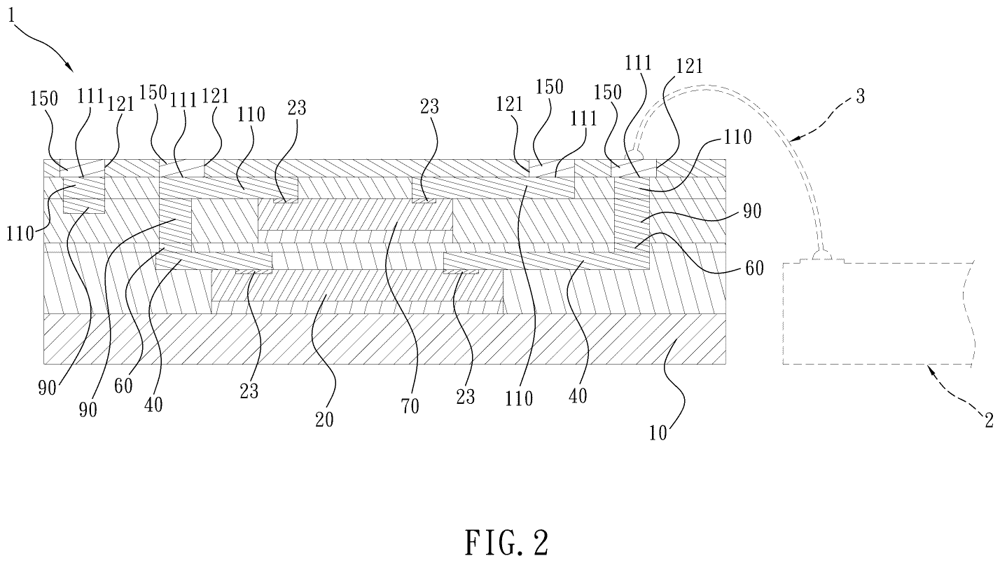

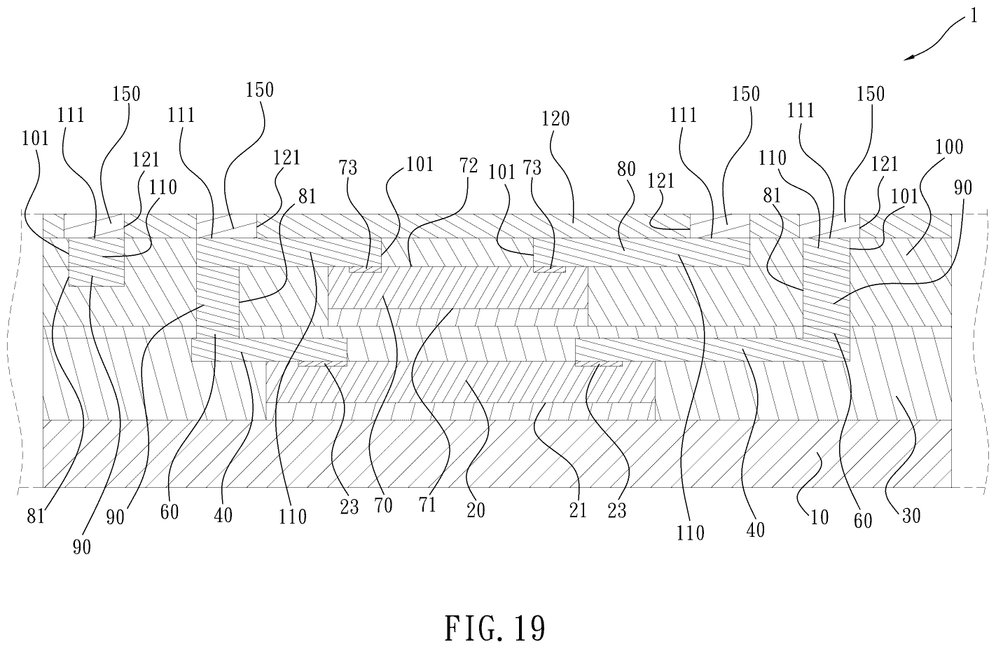

Refer to FIG. 19, each of the openings 121 is provided with a projection 150 which is electrically connected to the solder pad 111 in the opening 121 correspondingly. The FOWLP unit 1 forms welding points on the projection 150 and an electronic component 2 by wire bonding. The projection 150 and the electronic component 2 are electrically connected by a bonding wire 3, as shown in FIG. 2.

Compared with the FOWLP unit available now, the present FOWLP unit 1 has the following advantages.
(1) The steps S3 and S9 of the present method of manufacturing the present FOWLP unit 1 are simplified and easily-implemented steps and this is especially helpful in reduction of a thickness of the packaging unit. Thus the manufacturing process of the present invention is not only more simplified and with reduced cost, but also improving use efficiency and reliability of the FOWLP unit 1.
(2) The method of forming the first, the second, the third, and the fourth conductive circuits 40, 60, 90, 110 according to the present invention can effectively solve the problems generated during manufacturing of the respective conductive circuits by the FOWLP technology available now including higher manufacturing cost and less environmental benefit.
(3) The respective conductive circuits in the RDL of the present invention have electrical extension in the XY plane and interconnections. At the same time, the FOWLP unit 1 manufactured still has slim size and light weight to some extent. Thereby products with better performance (for example, the lower-layered die 20 and the upper-layered die 70 have the same specifications, effectiveness, or functions) or more functions (for example, the lower-layered die 20 and the upper-layered die 70 have different specifications, effectiveness, or functions) are provided and their market competitiveness is improved.
(4) The present FOWLP unit 1 is electrically connected to an electronic component 2 by the solder balls 140, as shown in FIG. 1, or forming welding points on the projection 150 and an electronic component 2 by wire bonding. The projection 150 and the electronic component 2 are electrically connected by a bonding wire 3, as shown in FIG. 2. The products have more diversified applications.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer level packaging (FOWLP) unit comprising:
a substrate having a first surface;
at least one lower-layered die cut from at least one wafer and having a first surface, a second surface opposite to the first surface, and a plurality of die pads disposed on the second surface; the first surface of the lower-layered die fixed on the first surface of the substrate;
a first dielectric layer covering the lower-layered die correspondingly and provided with a plurality of first slots extending horizontally; the die pads of the lower-layered die exposed through the first slots;
at least one first conductive circuit formed by a metal paste filled in the respective first slots; the first conductive circuit electrically connected to the die pads of the lower-layered die;
a second dielectric layer covering the lower-layered die correspondingly, located over first dielectric layer, and provided with a plurality of second slots extending horizontally; wherein the second slots are communicating with the first slots;
at least one second conductive circuit formed by a metal paste filled in the respective second slots; wherein the second conductive circuit is electrically connected to the first conductive circuit;
at least one upper-layered die cut from at least one wafer and having a first surface and a second surface opposite to the first surface; wherein the second surface is provided with a plurality of die pads and the first surface is fixed on the second dielectric layer; wherein an area just above the second surface is defined as a chip area;
a third dielectric layer covering the upper-layered die correspondingly and provided with a plurality of third slots extending horizontally;
wherein the die pads of the upper-layered die are electrically connected to the outside through the third slots;
at least one third conductive circuit formed by a metal paste filled into the respective third slots and the third conductive circuit electrically connected to the second conductive circuit;
a fourth dielectric layer covering the upper-layered die correspondingly, located over the third dielectric layer, and provided with a plurality of fourth slots extending horizontally; wherein the fourth slots are communicating with the third slots;
at least one fourth conductive circuit formed by a metal paste filled into the respective fourth slots; wherein the fourth conductive circuit is electrically connected to the third conductive circuit or the die pads of the upper-layered die; and
an outer protective layer disposed over the fourth dielectric layer and provided with a plurality of openings; at least one of the openings located around a chip area above the second surface of the lower-layered die, and the chip area above the second surface of the upper-layered die; wherein the fourth conductive circuit is exposed through the opening to form a solder pad in the opening;
wherein the lower-layered die and the upper-layered die respectively are disposed on an upper position and a lower position, corresponding to each other, and stacked on the substrate with an interval between them; wherein the lower-layered die is electrically connected to the upper-layered die through the first conductive circuit, the second conductive circuit, the third conductive circuit, and the fourth conductive circuit in turn; wherein the lower-layered die is also electrically connected to the outside through the first conductive circuit, the second conductive circuit, the third conductive circuit, the fourth conductive circuit, and the solder pads around the chip area above the second surface of the upper-layered die in turn; wherein the upper-layered die is electrically connected to the outside through the fourth conductive circuit and the solder pads around the chip area above the second surface of the upper-layered die to form the fan-out wafer level packaging (FOWLP) unit;
wherein a method of manufacturing the fan-out wafer level packaging (FOWLP) unit comprising the step of:
Step S1: providing a substrate;
Step S2: arranging a plurality of lower-layered dies cut from at least one wafer at the substrate and allowing a first surface of the respective lower-layered dies to be fixed on the substrate; wherein each of the lower-layered die is provided with a second surface opposite to the first surface and a plurality of die pads is disposed on the second surface of the lower-layered die;
Step S3: covering the lower-layered die with a first dielectric layer and forming a plurality of first slots horizontally on the first dielectric layer so that the respective die pads of the lower-layered die are exposed through the respective first slots; then filling a metal paste into the first slots and a level of the metal paste is higher than a surface of the first dielectric layer; later grinding the metal paste with the level higher than the surface of the first dielectric layer to make the surface of the metal paste flush with the surface of the first dielectric layer and form a plurality of first conductive circuits; next covering the first dielectric layer with a second dielectric layer and forming a plurality of second slots horizontally on the second dielectric layer so that the respective first conductive circuits in the first slots are exposed through the respective second slots; lastly filling a metal paste into the respective second slots and a level of the metal paste is higher than a surface of the second dielectric layer; then grinding the metal paste with the level higher than the surface of the second dielectric layer to make the surface of the metal paste flush with the surface of the second dielectric layer and form a plurality of second conductive circuits;
Step S4: disposing a plurality of upper-layered dies cut from at least one wafer on the second dielectric layer; wherein each of the upper-layered dies is provided with a first surface and a second surface opposite to the first surface; a plurality of die pads is disposed on the second surface of the respective upper-layered dies and an area just above the second surface of the upper-layered die is defined as a chip area;
Step S5: covering the respective upper-layered dies with a third dielectric layer and forming a plurality of third slots extending horizontally on the third dielectric layer so that the respective die pads of the respective upper-layered dies are exposed through the respective third slots of the third dielectric layer; then filling a metal paste into the respective third slots and a level of the metal paste is higher than a surface of the third dielectric layer; grinding the metal paste with the level higher than the surface of the third dielectric layer to make the surface of the metal paste flush with the surface of the third dielectric layer and form a plurality of third conductive circuits; next covering the third dielectric layer with a fourth dielectric layer and forming a plurality of fourth slots extending horizontally on the fourth dielectric layer so that the respective third conductive circuits in the respective fourth slots are exposed through the respective fourth slots; lastly filling a metal paste into the respective fourth slots and a level of the metal paste is higher than a surface of the fourth dielectric layer and then grinding the metal paste with the level higher than the surface of the fourth dielectric layer to make the surface of the metal paste flush with the surface of the fourth dielectric layer and form a plurality of fourth conductive circuits;
Step S6: covering the fourth dielectric layer with an outer protective layer;
Step S7: forming a plurality of openings on the outer protective layer and allowing at least one of the openings to be located around the chip area above the second surface of the respective upper-layered dies so that each of the fourth conductive circuits is exposed through the corresponding opening to form a solder pad in the opening; and
Step S8: performing cutting to form a plurality of the fan-out wafer-level packaging (FOWLP) units.

2. The FOWLP unit as claimed in claim 1, wherein an area just above the second surface of the lower-layered dies is defined as a chip area; each of the lower-layered dies is electrically connected to the outside through the first conductive circuit, the second conductive circuit, the third conductive circuit, the fourth conductive circuit, and the solder pads around the chip area above the second surface of the lower-layered die in turn.

3. The FOWLP unit as claimed in claim 1, wherein the upper-layered die and the lower-layered die are cut from the same wafer or different from wafers.

4. The FOWLP unit as claimed in claim 1, wherein the substrate includes silicon substrate, glass substrate, and ceramic substrate.

5. The FOWLP unit as claimed in claim 1, wherein the metal paste which forms the first conductive circuit, the second conductive circuit, the third conductive circuit, and the fourth conductive circuit includes silver paste, nano-silver paste, copper paste, and nano-copper paste.

6. The FOWLP unit as claimed in claim 1, wherein the first surface of the lower-layered die is disposed on the substrate by a die attach film (DAF); wherein the first surface of the upper-layered die is arranged at the second dielectric layer by a die attach film (DAF).

7. The FOWLP unit as claimed in claim 1, wherein each of the openings is provided with a solder ball which is electrically connected to the solder pad in the opening correspondingly; wherein the FOWLP unit is electrically connected to and disposed on an electronic component by the solder balls.

8. The FOWLP unit as claimed in claim 1, wherein each of the openings is provided with a projection which is electrically connected to the solder pad in the opening correspondingly; wherein the FOWLP unit forms welding points on the projection and an electronic component by wire bonding and the projection and the electronic component are electrically connected by a bonding wire.
